(19) United States
(12) Patent Application Publication
(10) Pub. No.: US 2026/0314185 A1
(43) Pub. Date: Oct. 8, 2026

(54) DISPLAY PANEL

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Li SUN, Beijing (CN); Guang YAN, Beijing (CN); Yan QU, Beijing (CN)

(21) Appl. No.: 19/478,800

(22) PCT Filed: May 14, 2024
(86) PCT No.: PCT/CN2024/093030

§ 371 Date: Oct. 24, 2025

(30) Foreign Application Priority Data
Jun. 7, 2023 (CN) 202310673319.X

(51) Int. Cl. H10K 59/122; H10K 59/12

(52) U.S. Cl. CPC H10K 59/122; H10K 59/1201

(57) ABSTRACT

A display panel includes a substrate, and first electrodes formed on the substrate. The display panel further includes a first pixel definition layer and a second pixel definition layer. first pixel definition layer is located on the substrate, has an opening exposing at least a portion of the first electrodes, and includes a main body and a protrusion surrounding an outer periphery of the main body. The second pixel definition layer is positioned on a side of the main body distal to the substrate. The first and second pixel definition layers together define a recess region, which is positioned on a side of the second pixel definition layer proximal to the substrate and between the main body and the protrusion. A light-emitting function layer is formed on a surface of the first electrodes distal to the substrate, and is broken in at least one recess region.

### CROSS-REFERENCE TO RELATED APPLICATIONS

This is a National Phase Application filed under 35 U.S.C. 371 as a national stage of PCT/CN2024/093030 filed on May 14, 2024, an application claiming priority to Chinese patent application No. 202310673319.X, filed on Jun. 7, 2023, the entire content of each of which is incorporated herein by reference.

### TECHNICAL FIELD

The present disclosure relates to the field of display technology, and in particular, to a display panel.

### BACKGROUND

In a conventional organic light-emitting diode (OLED) display panel, a pixel definition layer (PDL) is formed on a substrate, and the display panel has a plurality of sub-pixels formed through definition by the pixel definition layer. When power is turned on, carriers will migrate from a sub-pixel to an adjacent sub-pixel, and a current (i.e., an electric current) driving the sub-pixel to emit light will be transmitted to the adjacent sub-pixel, which causes the problem of light-emitting crosstalk, and results in poor display quality.

### SUMMARY

To solve at least one of the technical problems existing in the prior art, the present disclosure provides a display panel having improved crosstalk prevention capability and improved display quality.

To achieve the above object, the present disclosure provides a display panel, which includes: a substrate, a plurality of first electrodes, a pixel definition structure, and a light-emitting function layer;
the plurality of first electrodes are formed on the substrate;
the pixel definition structure includes a first pixel definition layer and a second pixel definition layer, wherein the first pixel definition layer is located on the substrate, the first pixel definition layer has an opening exposing at least a portion of the first electrodes, the first pixel definition layer includes a main body and a protrusion surrounding an outer periphery of the main body, the second pixel definition layer is positioned on a side of the main body distal to the substrate, at least a portion of an edge of the second pixel definition layer protrudes from the main body, the second pixel definition layer and the first pixel definition layer together define a recess region, the recess region is positioned on a side of the second pixel definition layer proximal to the substrate and between the main body and the protrusion; and
the light-emitting function layer is formed on a surface of the first electrodes distal to the substrate, wherein the light-emitting function layer is broken in at least one recess region.

In the display panel, an orthogonal projection of the second pixel definition layer on the substrate covers an orthogonal projection of the main body on the substrate, the recess region is in a shape of a ring, and the recess region surrounds an outer periphery of the main body.

In the display panel, the first pixel definition layer further includes a first definition sub-layer located on a side of the main body proximal to the substrate and between any adjacent two of the first electrodes, and an orthogonal projection of the main body on the substrate falls within an orthogonal projection of the first definition sub-layer on the substrate.

In the display panel, the first definition sub-layer is connected to a lateral side of each of the adjacent first electrodes, and a surface of the first definition sub-layer distal to the substrate is flush with a surface of at least one of the first electrodes distal to the substrate.

In the display panel, the first pixel definition layer further includes a second definition sub-layer located between the first definition sub-layer and the main body, and an orthogonal projection of at least a portion of the second definition sub-layer on the substrate covers the orthogonal projection of the first definition sub-layer on the substrate.

In the display panel, the orthogonal projection of the main body on the substrate falls within an orthogonal projection of the second pixel definition layer on the substrate; and the orthogonal projection of the second pixel definition layer on the substrate falls within an orthogonal projection of the second definition sub-layer on the substrate.

In the display panel, an edge of the second definition sub-layer is formed on a surface of an adjacent first electrode distal to the substrate.

In the display panel, the protrusion is formed on the surface of the adjacent first electrode distal to the substrate, the protrusion surrounds an outer periphery of the second definition sub-layer, and the second definition sub-layer abuts an inner peripheral surface of the protrusion.

In the display panel, in a direction parallel to the substrate, a distance between an inner peripheral surface of the protrusion toward the recess region and an outer peripheral surface of the main body toward the recess region in a radial direction of the protrusion is a first distance; a distance between the inner peripheral surface of the protrusion and an outer peripheral surface of the first definition sub-layer in the radial direction of the protrusion is a second distance, and the first distance is greater than the second distance.

In the display panel, in a direction parallel to the substrate, a distance between an inner peripheral surface of the protrusion toward the recess region and an outer peripheral surface of the main body toward the recess region in a radial direction of the protrusion is less than or equal to a thickness of the second pixel definition layer.

In the display panel, a size by which the second pixel definition layer protrudes from the main body is less than a height of the main body in a direction perpendicular to the substrate.

In the display panel, in a direction perpendicular to the substrate, a height of the protrusion is less than or equal to a height of the main body and is greater than a thickness of the second pixel definition layer.

In the display panel, the protrusion and the first definition sub-layer are disposed in a same layer, or the protrusion and the main body are disposed in a same layer.

In the display panel, the pixel definition structure further includes a third pixel definition layer, which is located on a side of the protrusion distal to the substrate, and at least partially laps with an outer peripheral surface of the protrusion and a surface of the protrusion distal to the substrate.

In the display panel, the third pixel definition layer and the second pixel definition layer are arranged in a same layer.

The present disclosure has the following beneficial technical effects.

In the display panel provided by the present disclosure, by forming the recess region between the first pixel definition layer and the second pixel definition layer of the pixel definition structure, the light-emitting function layer can be broken (or disconnected) at the position of the recess region, and thus the light-emitting function layer is discontinuous. As such, when a first electrode is powered on, a migration path of carriers migrating to an adjacent sub-pixel under the action of an electric field is cut off at the broken (or disconnected) position, so that the carriers cannot diffuse to a portion of the light-emitting function layer corresponding to the pixel definition structure, the migration of the carriers to the adjacent sub-pixel is prevented, which is beneficial to avoiding a crosstalk, thereby improving the display quality of the display panel, and improving the uniformity of light emission.

### BRIEF DESCRIPTION OF THE DRAWINGS

FIG. 1 is a schematic cross-sectional view illustrating a part of a display panel according to the related art;

FIG. 2 is a schematic cross-sectional view illustrating a part of a display panel, in which a pixel definition structure is formed on a substrate, according to an embodiment of the present disclosure;

FIG. 3 is a schematic cross-sectional view illustrating a part of another display panel, in which a pixel definition structure is formed on a substrate, according to an embodiment of the present disclosure;

FIG. 4 is a schematic cross-sectional view illustrating a part of the display panel shown in FIG. 3; and

FIG. 5 is a schematic diagram illustrating a manufacturing process of a method for manufacturing a display panel according to an embodiment of the present disclosure.

Description of the reference symbols is as follows:
100—display panel;
10—substrate;
20—first electrode;
30—pixel definition structure; 31—first pixel definition layer; 311—first definition sub-layer; 312—second definition sub-layer; 313—third definition sub-layer; 3131-main body; 3132—protrusion; 314—initial third definition sub-layer; 32—second pixel definition layer; 33—recess region; 34—third pixel definition layer; and 35—initial pixel definition layer; and
40—light—emitting function layer; and 41—gap.

### DETAILED DESCRIPTION OF EMBODIMENTS

To make one of ordinary skill in the art better understand technical solutions of the present disclosure, a display panel provided by the present disclosure will be described in detail below with reference to the accompanying drawings.

FIG. 1 is a schematic cross-sectional view illustrating a part of a display panel according to the related art. As shown in FIG. 1, a pixel definition layer 30a and a plurality of first electrodes 20a are formed on a substrate 10a of a display panel 100a. The pixel definition layer 30a is disposed around each of the first electrodes 20a. The pixel definition layer 30a defines a plurality of sub-pixels on the substrate 10a, and organic layers 40a of the sub-pixels are formed on surfaces of the respective first electrodes 20a distal to the substrate 10a. The organic layers 40a of adjacent sub-pixels are connected to each other. A size of the pixel definition layer 30a in a first direction (denoted by “L” in FIG. 1) is equivalent to a size of a respective sub-pixel in the first direction. A second electrode is formed on a surface of each organic layer 40a distal to the substrate 10a. When a first electrode 20a is connected to a power source, carriers will migrate toward a respective second electrode. Some of the carriers move in a thickness direction of the substrate 10a, and the flow path thereof is shown by the solid arrow as indicated in FIG. 1. Meanwhile, some of the carriers have a displacement in the first direction while moving toward the respective second electrodes, may diffuse to the organic layer 40a corresponding to the pixel definition layer 30a, may even diffuse to an adjacent sub-pixel, and the flow path thereof is shown by the dotted arrows as indicated in FIG. 1. Thus, when a sub-pixel is turned on, a current driving the sub-pixel to emit light is transmitted to another sub-pixel adjacent to the sub-pixel, which causes the problem of light-emitting crosstalk, low uniformity of light emitted from pixels, and poor display quality.

To solve the above problems, embodiments of the present disclosure provide a display panel, which will be described in detail below with reference to the accompanying drawings.

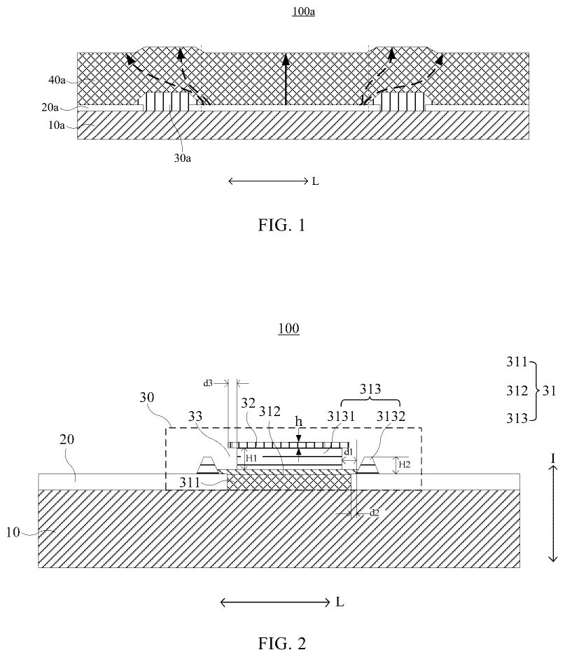

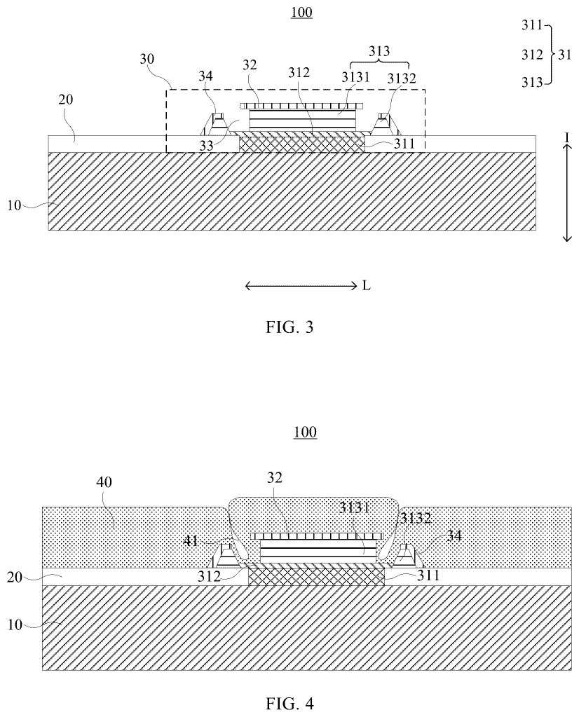

FIG. 2 is a schematic cross-sectional view illustrating a part of a display panel, in which a pixel definition structure is formed on a substrate, according to an embodiment of the present disclosure, and FIG. 3 is a schematic cross-sectional view illustrating a part of another display panel, in which a pixel definition structure is formed on a substrate, according to an embodiment of the present disclosure. Referring to FIGS. 2 and 3, the display panel 100 includes a substrate 10, a first electrode layer, and a pixel definition structure 30.

The first electrode layer is formed on the substrate 10, and includes a plurality of first electrodes 20.

The pixel definition structure 30 includes a first pixel definition layer 31 and a second pixel definition layer 32. The first pixel definition layer 31 is located on the substrate 10, and has an opening configured to define a light-emitting region of a sub-pixel. The opening also enables at least a portion of a respective first electrode 20 to be exposed. Further, the first pixel definition layer 31 includes a main body 3131 and a protrusion 3132. The protrusion 3132 is a ring-shaped structure, and surrounds an outer periphery of the main body 3131. A cross-sectional shape of the protrusion 3132 is not limited to a trapezoid shown in FIG. 2, and may alternatively be a rectangle, a triangle, or the like, which is not particularly limited in the present embodiment.

The second pixel definition layer 32 is located on a side of the main body 3131 distal to the substrate 10, and at least a portion of an edge of the second pixel definition layer 32 protrudes from the main body 3131.

As such, the portion of the second pixel definition layer 32 protruding from the main body 3131 and the first pixel definition layer 31 together define a recess region 33, and the recess region 33 is located on a side of the second pixel definition layer 32 proximal to the substrate 10 and between the main body 3131 and the protrusion 3132. It should be understood that in a case where the edge of the second pixel definition layer 32 protrudes to form a plurality of flanges and each of the flanges extends beyond the main body 3131, each of the flanges and the first pixel definition layer 31 may define a corresponding recess region 33, and in this case, a plurality of recess regions 33 will be formed.

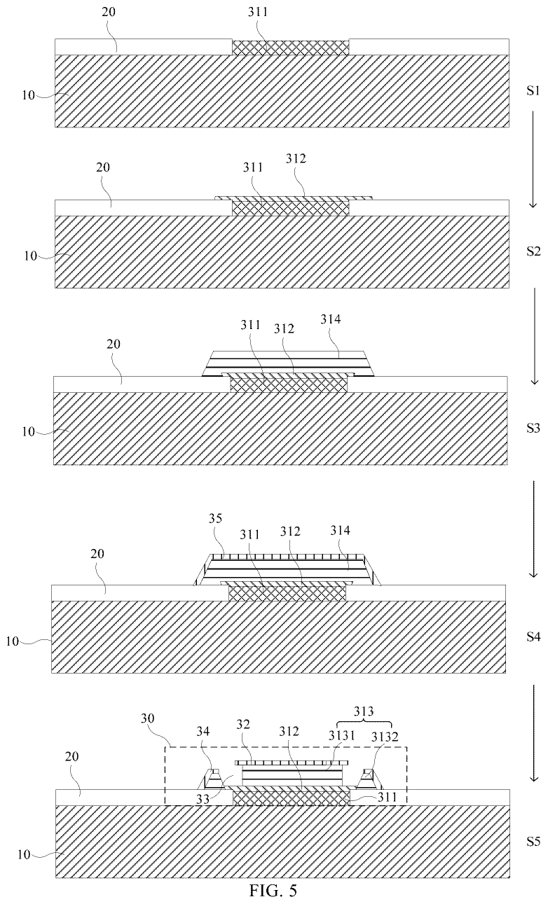

FIG. 4 is a schematic cross-sectional view illustrating a part of the display panel 100 shown in FIG. 3. As shown in FIG. 4, a light-emitting function layer 40 is formed on a surface of each first electrode 20 distal to the substrate 10. Here, the light-emitting function layer 40 is formed by an evaporation process. Specifically, an evaporation coating material is heated and vaporized by an evaporation source, and stays in a limited region through the through holes of an evaporation mask. Since the pixel definition structure 30 has the recess region 33, the pixel definition structure 30 forms an evaporation shadow at a position corresponding to the recess region 33. The flow of the evaporation coating material toward the recess region 33 is blocked by the protrusion 3132 and the portion of the second pixel definition layer 32 protruding from the main body 3131, so that the evaporation coating material can only diffuse into the recess region 33 through an opening of the recess region 33, and is difficult to fill the entire recess region 33. Thus, the light-emitting function layer 40 formed by evaporation is broken (or disconnected) by forming a gap 41 in at least one recess region 33 due to the effect of shadow. It should be understood that a size and a shape of the gap 41 are related to the recess region 33. For example, one end of the gap 41 may extend to a surface of the light-emitting function layer 40 proximal to the substrate 10, and/or the other end of the gap 41 may extend to a surface of the light-emitting function layer 40 distal to the substrate 10.

In the display panel 100 according to the present embodiment, since the pixel definition structure 30 has the recess regions 33, the light-emitting function layer 40 can be broken (or disconnected) at the position of at least one of the recess regions 33, and the light-emitting function layer 40 cannot be formed as a continuous film, so that the portion of the light-emitting function layer 40 for two adjacent sub-pixels is not continuous at the broken (or disconnected) position. As such, when the first electrode 20 is powered on, carriers migrate to the outer side of the light-emitting function layer 40 distal to the substrate 10 under the action of an electric field, and even if some of the carriers have a displacement in the first direction, a migration path of the carriers is cut off due to the broken (or disconnected) position, so that the carriers cannot diffuse to a portion of the light-emitting function layer 40 corresponding to the pixel definition structure 30, and the carriers are prevented from being transmitted to an adjacent sub-pixel, which is beneficial to avoiding crosstalk, and is beneficial to improving the display quality of the display panel 100 and improving the uniformity of light emission.

Further, there is uncertainty about a diffusion direction of the evaporation coating material, and the flow path of the evaporation coating material into each recess region 33 becomes certain by providing the recess region 33 between the protrusion 3132 and the main body 3131 in the present embodiment. As such, a degree of controllability of each broken (or disconnected) position of the light-emitting function layer 40 is increased to ensure that each broken (or disconnected) position is limited within the recess region 33, and thus each broken (or disconnected) position is effectively confined to the pixel definition structure 30 and is close to a respective sub-pixel, to ensure that carriers can be intercepted at each broken (or disconnected) position when flowing to an adjacent sub-pixel.

In some embodiments, the display panel 100 further includes a second electrode (not shown) formed on a surface of the light-emitting function layer 40 distal to the substrate 10. Each first electrode 20 and the second electrode are of opposite polarity. For example, each first electrode 20 is an anode, and the second electrode is a cathode; alternatively, each first electrode 20 is a cathode, and the second electrode is an anode.

It should be understood that the second pixel definition layer 32 is not limited to having only a portion of the edge protruding from the main body 3131. In some embodiments, the entire edge of the second pixel definition layer 32 protrudes from the main body 3131, and in this case, an orthogonal projection of the second pixel definition layer 32 on the substrate 10 covers an orthogonal projection of the main body 3131 on the substrate 10. In the present embodiment, the recess region 33 is in a shape of a ring, and the recess region 33 surrounds the outer periphery of the main body 3131.

Since the entire edge of the second pixel definition layer 32 extends beyond a surface of the main body 3131 distal to the substrate 10, a region of the second pixel definition layer 32 extending beyond the main body 3131 may be regarded as a brim (or visor) of a hat. Compared with the pixel definition structure 30 having a plurality of recess regions 33 spaced apart from each other, so designed recess region 33 in the present embodiment has a ring-shape, such that the evaporation shadow is larger, which is beneficial to ensuring that the light-emitting function layer 40 is broken (or disconnected) at the position of the recess region 33, and is beneficial to increasing the number of broken (or disconnected) portions of the light-emitting function layer 40, thereby being beneficial to enhancing the effect of intercepting (or blocking) the carriers.

With continued reference to FIGS. 2 to 4, the first pixel definition layer 31 further includes a first definition sub-layer 311. The first definition sub-layer 311 is disposed on a side of the main body 3131 proximal to the substrate 10, and is disposed between two adjacent first electrodes 20, so as to space the two adjacent first electrodes 20 apart from each other. The main body 3131 is formed on a side of the first definition sub-layer 311 distal to the substrate 10. As such, the first definition sub-layer 311 can provide support for the main body 3131. It should be noted that the orthogonal projection of the main body 3131 on the substrate 10 is located within an orthogonal projection of the first definition sub-layer 311 on the substrate 10, so that the first definition sub-layer 311 can stably support the main body 3131.

With continued reference to FIGS. 2 and 3, the first pixel definition layer 31 further includes a second definition sub-layer 312 located between the first definition sub-layer 311 and the main body 3131, and the second definition sub-layer 312 is formed on a surface of the first definition sub-layer 311 distal to the substrate 10. That is, the first definition sub-layer 311, the second definition sub-layer 312, and the main body 3131 are sequentially stacked from the substrate 10 toward the light-emitting function layer 40.

Here, an orthogonal projection of at least a portion of the second definition sub-layer 312 on the substrate 10 covers the orthogonal projection of the first definition sub-layer 311 on the substrate 10.

In one case, the orthogonal projection of the entire second definition sub-layer 312 on the substrate 10 covers the orthogonal projection of the first definition sub-layer 311 on the substrate 10, i.e., the orthogonal projection of the second definition sub-layer 312 on the substrate 10 and the orthogonal projection of the first definition sub-layer 311 on the substrate 10 completely coincide with each other.

In another case, the orthogonal projection of only a portion of the second definition sub-layer 312 on the substrate 10 covers the orthogonal projection of the first definition sub-layer 311 on the substrate 10, i.e., the orthogonal projection of the first definition sub-layer 311 on the substrate 10 falls within the orthogonal projection of the second definition sub-layer 312 on the substrate 10.

In a further alternative example, an edge of the second definition sub-layer 312 is formed on a surface of the first electrode 20 distal to the substrate 10. That is, a portion of the second definition sub-layer 312 laps with (i.e., overlaps with and is connected to) the first electrode 20. As such, the second definition sub-layer 312 can cover a peripheral portion of the first electrode 20, which is advantageous for preventing the first electrode 20 from leaking electricity.

In some examples of the present disclosure, the orthogonal projection of the second pixel definition layer 32 on the substrate 10 and the orthogonal projection of the second definition sub-layer 312 on the substrate 10 may completely coincide with each other, and the orthogonal projection of the main body 3131 on the substrate 10 falls within the orthogonal projection of the second pixel definition layer 32 on the substrate 10. Thus, the second definition sub-layer 312, the main body 3131, and the second pixel definition layer 32 are stacked together to form an I-shape. As an alternative embodiment, as shown in FIGS. 2 to 4, the orthogonal projection of the main body 3131 on the substrate 10 falls within the orthogonal projection of the second pixel definition layer 32 on the substrate 10, and the orthogonal projection of the second pixel definition layer 32 on the substrate 10 falls within the orthogonal projection of the second definition sub-layer 312 on the substrate 10.

In some embodiments, the protrusion 3132 is formed on the surface of the first electrode 20 distal to the substrate 10, and protrudes from the surface of the first electrode 20 distal to the substrate 10 toward the light-emitting function layer 40. The protrusion 3132 surrounds an outer periphery of the second definition sub-layer 312, and the second definition sub-layer 312 abuts an inner peripheral surface of the protrusion 3132. In the present embodiment, the recess region 33 is defined by the second definition sub-layer 312, the main body 3131, the protrusion 3132, and the second pixel definition layer 32. As such, the protrusion 3132 can also cover a portion of the outer periphery of the first electrode 20, thereby improving the ability of preventing the first electrode 20 from leaking electricity.

Further, in a case where the gap 41 penetrates through the light-emitting function layer 40, during a process of forming the second electrode on the light-emitting function layer 40, a material thereof may enter into the gap 41 to further form the second electrode in the gap 41, and in this case, the second definition sub-layer 312 can play a role of insulation to insulate the first electrode 20 from the second electrode. That is, even if the gap 41 penetrates through the light-emitting function layer 40 and a material for forming the second electrode is filled in the gap 41, under the separation effect of the second definition sub-layer 312, the first electrode 20 and the second electrode will not be short-circuited with each other due to being in contact with each other.

As shown in FIGS. 2 to 3, in some embodiments, the first definition sub-layer 311 is connected with a lateral side of each of adjacent first electrodes 20, and a surface of the first definition sub-layer 311 distal to the substrate 10 is flush with a surface of at least one of the adjacent first electrodes 20 distal to the substrate 10. Here, it should be noted that, the surface of the first definition sub-layer 311 distal to the substrate 10 being flush with the surface of each of the first electrodes 20 distal to the substrate 10 is not limited to being geometrically absolute flush with each other, and may include a case where a height difference between the surface of the first definition sub-layer 311 distal to the substrate 10 and the surface of each of the first electrodes 20 distal to the substrate 10 varies within 10% of a thickness of the first definition sub-layer 311, affected by factors such as process errors.

Alternatively, in other embodiments of the present disclosure, the surface of the first definition sub-layer 311 distal to the substrate 10 may be located between the substrate 10 and the surface of each first electrode 20 distal to the substrate 10.

In some examples, in a direction parallel to the substrate 10 (i.e., a radial direction of the protrusion 3132), a distance between an inner peripheral surface of the protrusion 3132 toward the recess region 33 and an outer peripheral surface of the main body 3131 toward the recess region 33 is a first distance d1, and a distance between the inner peripheral surface of the protrusion 3132 and an outer peripheral surface of the first definition sub-layer 311 is a second distance d2, where d1>d2. It should be understood that, in a case where a cross-sectional shape of the protrusion 3132 is a rectangle, the distance between the inner peripheral surface of the protrusion 3132 and the outer peripheral surface of the main body 3131 is a constant in the radial direction of the protrusion 3132, i.e., is the first distance d1; in a case where the cross-sectional shape of the protrusion 3132 is a trapezoid, the first distance d1 is a minimum distance between the inner peripheral surface of the protrusion 3132 and the outer peripheral surface of the main body 3131 in the radial direction of the protrusion 3132. Similarly, the second distance d2 may be defined similarly to the above defined first distance d1.

In some examples, in the direction parallel to the substrate 10 (i.e., the radial direction of the protrusion 3132), the distance between the inner peripheral surface of the protrusion 3132 toward the recess region 33 and the outer peripheral surface of the main body 3131 toward the recess region 33 is not greater than a thickness of the second pixel definition layer 32. That is, the first distance d1 is less than or equal to the thickness h of the second pixel definition layer 32.

In some examples, a size d3 by which the second pixel definition layer 32 protrudes from the main body 3131 is less than a height H1 of the main body 3131 in a direction perpendicular to the substrate 10 (i.e., in the direction I as shown in FIG. 2).

In some examples, in the direction perpendicular to the substrate 10, a height H2 of the protrusion 3132 is not greater than the height H1 of the main body 3131 and is greater than the thickness h of the second pixel definition layer 32. In other words, h<H2≤H1.

There are many possible cases in an order for forming the protrusion 3132 during forming of the pixel definition structure 30.

For example, in one possible case, the protrusion 3132 and the first definition sub-layer 311 may be formed by a same process. That is, the protrusion 3132 and the first definition sub-layer 311 may be formed in a same layer.

For another example, in one possible case, the protrusion 3132 and the second definition sub-layer 312 may be formed by a same process. That is, the protrusion 3132 and the second definition sub-layer 312 may be formed in a same layer.

For another example, in one possible case, as shown in FIG. 3, the protrusion 3132 and the main body 3131 may be formed by a same process. That is, the protrusion 3132 and the main body 3131 may be formed in a same layer. In this case, the protrusion 3132 and the main body 3131 have a one-piece structure to form a third definition sub-layer 313. Specifically, the pixel definition structure 30 in the present embodiment includes the first definition sub-layer 311, the second definition sub-layer 312, the third definition sub-layer 313, and the second pixel definition layer 32, which are sequentially stacked together.

In one particular example, the pixel definition structure 30 further includes a third pixel definition layer 34. The third pixel definition layer 34 is located on a side of the protrusion 3132 distal to the substrate 10, and at least a portion of the third pixel definition layer 34 laps with an outer peripheral surface of the protrusion 3132 and a surface of the protrusion 3132 distal to the substrate 10. Specifically, for example, as shown in FIGS. 3 and 4, the third pixel definition layer 34 covers at least a portion of the outer peripheral surface of the ring-shaped protrusion 3132 and at least a portion of the surface of the protrusion 3132 distal to the substrate 10.

It is to be understood that the third pixel definition layer 34 and the second pixel definition layer 32 may be formed by a same process. That is, the third pixel definition layer 34 and the second pixel definition layer 32 may be formed in a same layer. Alternatively, in some optional examples, the third pixel definition layer 34 and the second pixel definition layer 32 are formed by different processes. In the case where the third pixel definition layer 34 and the second pixel definition layer 32 are formed in a same layer, the manufacturing efficiency is high.

In the embodiment where the pixel definition structure 30 has the third pixel definition layer 34 as shown in FIG. 3, taking an example where the third pixel definition layer 34 and the second pixel definition layer 32 are formed in a same layer, and where the main body 3131 and the protrusion 3132 are formed in a same layer, a flow of manufacturing process of the pixel definition structure 30 in the present embodiment may be that shown in FIG. 5. FIG. 5 is a schematic view of a manufacturing process of a method for manufacturing the display panel 100 according to an embodiment of the present disclosure.

The manufacturing process of the pixel definition structure 30 may be realized by the following steps S1 to S5.

Step S1 includes forming the first definition sub-layer 311 on the substrate 10, where the first definition sub-layer 311 spaces adjacent two first electrodes 20 apart from each other.

Step S2 includes forming the second definition sub-layer 312 on the surface of the first definition sub-layer 311 and the first electrodes 20 distal to the substrate 10.

Step S3 includes forming an initial third definition sub-layer 314 on a side of the second definition sub-layer 312 distal to the substrate 10.

Step S4 includes forming an initial pixel definition layer 35 on a surface of the initial third definition sub-layer 314 distal to the substrate 10.

Step S5 includes etching the initial third definition sub-layer 314 and the initial pixel definition layer 35 so that the initial third definition sub-layer 314 forms the third definition sub-layer 313, and the initial pixel definition layer 35 forms the second pixel definition layer 32 and the third pixel definition layer 34, where the third definition sub-layer 313 includes the main body 3131 and the protrusion 3132.

The forming the first definition sub-layer 311 on the substrate 10 in step S1 may include: depositing the first definition sub-layer 311 on the substrate 10, exposing the first definition sub-layer 311, and etching the first definition sub-layer 311.

Step S2 may specifically include: depositing the second definition sub-layer 312 on the surface of the first definition sub-layer 311 and the first electrodes 20 distal to the substrate 10, exposing the second definition sub-layer 312, and etching the second definition sub-layer 312.

Step S3 may specifically include: depositing the initial third definition sub-layer 314 on the side of the second definition sub-layer 312 distal to the substrate 10, and etching the initial third definition sub-layer 314.

Step S4 may specifically include: depositing the initial pixel definition layer 35 on the surface of the initial third definition sub-layer 314 distal to the substrate 10, and etching the initial pixel definition layer 35.

Specific implementation manners of deposition to form a layer include, but are not limited to, magnetron sputtering, thermal evaporation, plasma enhanced chemical vapor deposition (PECVD), and the like.

It should be understood that the above embodiments are merely exemplary embodiments adopted to illustrate the principles of the present disclosure, and the present disclosure is not limited thereto. It will be apparent to one of ordinary skill in the art that various modifications and improvements may be made therein without departing from the spirit and scope of the present disclosure, and such modifications and improvements are also considered to fall within the scope of the present disclosure.

1. A display panel (100), comprising:
a substrate (10);
a plurality of first electrodes (20) formed on the substrate (10);
a pixel definition structure (30) comprising a first pixel definition layer (31) and a second pixel definition layer (32), wherein the first pixel definition layer (31) is located on the substrate (10), the first pixel definition layer (31) has an opening exposing at least a portion of the first electrodes (20), the first pixel definition layer (31) comprises a main body (3131) and a protrusion (3132) surrounding an outer periphery of the main body (3131), the second pixel definition layer (32) is positioned on a side of the main body (3131) distal to the substrate (10), at least a portion of an edge of the second pixel definition layer (32) protrudes from the main body (3131), the second pixel definition layer (32) and the first pixel definition layer (31) together define a recess region (33), the recess region (33) is positioned on a side of the second pixel definition layer (32) proximal to the substrate (10) and between the main body (3131) and the protrusion (3132); and
a light-emitting function layer (40) formed on a surface of the first electrodes (20) distal to the substrate (10), wherein the light-emitting function layer (40) is broken in at least one recess region (33).

2. The display panel (100) according to claim 1, wherein an orthogonal projection of the second pixel definition layer (32) on the substrate (10) covers an orthogonal projection of the main body (3131) on the substrate (10), the recess region

(33) is in a shape of a ring, and the recess region (33) surrounds an outer periphery of the main body (3131).

3. The display panel (100) according to claim 1, wherein the first pixel definition layer (31) further comprises a first definition sub-layer (311) located on a side of the main body (3131) proximal to the substrate (10) and between any adjacent two of the first electrodes (20), and an orthogonal projection of the main body (3131) on the substrate (10) falls within an orthogonal projection of the first definition sub-layer (311) on the substrate (10).

4. The display panel (100) according to claim 3, wherein the first definition sub-layer (311) is connected to a lateral side of each of the adjacent first electrodes (20), and a surface of the first definition sub-layer (311) distal to the substrate (10) is flush with a surface of at least one of the first electrodes (20) distal to the substrate.

5. The display panel (100) according to claim 3, wherein the first pixel definition layer (31) further comprises a second definition sub-layer (312) located between the first definition sub-layer (311) and the main body (3131), and an orthogonal projection of at least a portion of the second definition sub-layer (312) on the substrate (10) covers the orthogonal projection of the first definition sub-layer (311) on the substrate (10).

6. The display panel (100) according to claim 5, wherein the orthogonal projection of the main body (3131) on the substrate (10) falls within an orthogonal projection of the second pixel definition layer (32) on the substrate (10); and
the orthogonal projection of the second pixel definition layer (32) on the substrate (10) falls within an orthogonal projection of the second definition sub-layer (312) on the substrate (10).

7. The display panel (100) according to claim 6, wherein an edge of the second definition sub-layer (312) is formed on a surface of an adjacent first electrode (20) distal to the substrate (10).

8. The display panel (100) according to claim 7, wherein the protrusion (3132) is formed on the surface of the adjacent first electrode (20) distal to the substrate (10), the protrusion (3132) surrounds an outer periphery of the second definition sub-layer (312), and the second definition sub-layer (312) abuts an inner peripheral surface of the protrusion (3132).

9. The display panel (100) according to claim 8, wherein in a direction parallel to the substrate (10), a distance between an inner peripheral surface of the protrusion (3132) toward the recess region (33) and an outer peripheral surface of the main body (3131) toward the recess region (33) in a radial direction of the protrusion (3132) is a first distance; and
a distance between the inner peripheral surface of the protrusion (3132) and an outer peripheral surface of the first definition sub-layer (311) in the radial direction of the protrusion (3132) is a second distance, and the first distance is greater than the second distance.

10. The display panel (100) according to claim 1, wherein in a direction parallel to the substrate (10), a distance between an inner peripheral surface of the protrusion (3132) toward the recess region (33) and an outer peripheral surface of the main body (3131) toward the recess region (33) in a radial direction of the protrusion (3132) is less than or equal to a thickness of the second pixel definition layer (32).

11. The display panel (100) according to claim 1, wherein a size by which the second pixel definition layer (32) protrudes from the main body (3131) is less than a height of the main body (3131) in a direction perpendicular to the substrate (10).

12. The display panel (100) according to claim 1, wherein in a direction perpendicular to the substrate (10), a height of the protrusion (3132) is less than or equal to a height of the main body (3131) and is greater than a thickness of the second pixel definition layer (32).

13. The display panel (100) according to claim 3, wherein the protrusion (3132) and the first definition sub-layer (311) are disposed in a same layer, or the protrusion (3132) and the main body (3131) are disposed in a same layer.

14. The display panel (100) according to claim 1, wherein the pixel definition structure (30) further comprises a third pixel definition layer (34), which is located on a side of the protrusion (3132) distal to the substrate (10), and at least partially laps with an outer peripheral surface of the protrusion (3132) and a surface of the protrusion (3132) distal to the substrate (10).

15. The display panel (100) according to claim 14, wherein the third pixel definition layer (34) and the second pixel definition layer (32) are arranged in a same layer.

16. The display panel (100) according to claim 2, wherein the pixel definition structure (30) further comprises a third pixel definition layer (34), which is located on a side of the protrusion (3132) distal to the substrate (10), and at least partially laps with an outer peripheral surface of the protrusion (3132) and a surface of the protrusion (3132) distal to the substrate (10).

17. The display panel (100) according to claim 3, wherein the pixel definition structure (30) further comprises a third pixel definition layer (34), which is located on a side of the protrusion (3132) distal to the substrate (10), and at least partially laps with an outer peripheral surface of the protrusion (3132) and a surface of the protrusion (3132) distal to the substrate (10).

18. The display panel (100) according to claim 4, wherein the pixel definition structure (30) further comprises a third pixel definition layer (34), which is located on a side of the protrusion (3132) distal to the substrate (10), and at least partially laps with an outer peripheral surface of the protrusion (3132) and a surface of the protrusion (3132) distal to the substrate (10).

19. The display panel (100) according to claim 5, wherein the pixel definition structure (30) further comprises a third pixel definition layer (34), which is located on a side of the protrusion (3132) distal to the substrate (10), and at least partially laps with an outer peripheral surface of the protrusion (3132) and a surface of the protrusion (3132) distal to the substrate (10).

20. The display panel (100) according to claim 6, wherein the pixel definition structure (30) further comprises a third pixel definition layer (34), which is located on a side of the protrusion (3132) distal to the substrate (10), and at least partially laps with an outer peripheral surface of the protrusion (3132) and a surface of the protrusion (3132) distal to the substrate (10).
